(19) United States
(12) Patent Application Publication
(10) Pub. No.: US 2003/0062950 A1
(43) Pub. Date: Apr. 3, 2003

(54) Transmission power controller circuit

(76) Inventors: Kunihiro Hamada, Yokoham-Shi (JP); Kenichi Tanaka, Yokohama-Shi (JP)

Correspondence Address: MOTOROLA INC, 600 NORTH US HIGHWAY 45, LIBERTYVILLE, IL, 60048-5343, US

(21) Appl. No.: 10/253,551

(22) Filed: Sep. 24, 2002

(30) Foreign Application Priority Data
Sep. 28, 2001 (JP) 2001-302489

(51) Int. Cl. H03G 3/00

(52) U.S. Cl. 330/127

(57) ABSTRACT

To enhance the accuracy of transmission power control in radio transmission, in a transmission power control circuit, a transmission power level is determined by selecting any one of a plurality of predefined direct-current (DC) voltage levels. The transmission power control circuit includes a variable-gain amplifier portion (208, 308, 408) wherein an amplitude-modulated signal is input and the amplification gain is varied according to a gain control signal; a power amplifier portion (210, 310, 410) for supplying a transmission output signal; a power detector portion (220, 320, 420), coupled to a coupler for extracting a portion of the transmission output signal, for detecting the transmission output signal; and a reference voltage generator portion. The reference voltage signal is determined based on the DC voltage level value selected and a signal capable of extracting an envelope component.

### BACKGROUND OF THE INVENTION

The present invention relates in general to power control in radio transmission, and more specifically to a control circuit capable of enhancing the accuracy of transmission power control.

FIG. 1 shows a partial schematic diagram of a prior art transmitter (100) capable of controlling transmission power. The architecture and operation of the transmitter (100) is described hereinbelow. Digital-to-analog converters (104) for receiving in-phase (I) and quadrature (Q) components (102) of a baseband signal to be transmitted on respective signal paths are connected to a modulator (106) for performing amplitude modulation. An output of the modulator (106) is coupled to an input of a variable-gain amplifier (108). An output of the variable-gain amplifier (108) is coupled to an input of a power amplifier (110). Further, an output of the power amplifier (110) is coupled via an isolator (112) to a duplexer (114), so that a transmission output signal is transmitted from an antenna (116). A portion of the output of the power amplifier (110) is fed via a coupler (118) to a power detector (120). An output of the power detector (120) is coupled via a logarithmic amplifier (132) to one input of a comparator (134). The other input of the comparator (134) is coupled to a supply portion (136) that supplies one of a plurality of voltage levels provided to vary the transmission output. An output of the comparator (134) is coupled to a control input of the variable-gain amplifier (108).

The operation thereof is now described. After the signal to be transmitted is converted to a baseband analog signal by the digital-to-analog converter (104), the in-phase (I) and quadrature (Q) components are combined in the modulator (106) and converted to an amplitude-modulated modulation signal having a predetermined intermediate frequency. Further, the modulation signal is coupled to an input of a mixer (not shown), and mixed with a carrier frequency signal provided to the other input of the mixer, before being provided to the variable-gain amplifier (108). The variable-gain amplifier (108) variably amplifies the gain based on the output content of the comparator (134), and the transmission output signal transmitted from the antenna (116) via the power amplifier (110) is obtained. On the other hand, a portion of the output of the power amplifier (110) is supplied via the coupler (118) to the power detector (120) so that a signal with the carrier frequency component removed from the transmission output signal is output. The signal output from the power detector (120) is scaled by the logarithmic amplifier (132). Then, (the level of) the resulting scaled signal and the DC voltage level from the supply portion (136) are compared by the comparator (134), and the variable-gain amplifier (108) is controlled by the difference therebetween. In this way, radio transmission is conducted with power corresponding to the DC voltage level selected.

The power detector (120) coupled to the coupler (118) includes: a limiter (122) having, as an input thereof, the output from the coupler (118); a mixer (124) having the output from the coupler (118) coupled to one input thereof, and the output from the limiter (122) coupled to the other input thereof; and a low-pass filter (126) for low-pass filtering the output from the mixer (124). Assuming that the transmission output signal extracted from the coupler (118) is A(t) sin (wt+p), then the signal output by the mixer (124) is:

A(t)sin(wt+p)·K sin(wt+p)=(A(t)·K)/2 sin(2wt+2p)+(A(t)·K)/2 (1)

where A(t) is an envelope component of the transmission output signal; w is a radio carrier angular frequency; and K is a constant amplitude value defined by the limiter (122). The first term on the right-hand side of Eq. (1) is removed by passing through the low-pass filter (126), so that the signal output by the power detector (120) is (A(t)·K)/2. Although K is a fixed value, A(t) is an envelope component, which varies depending on the content of the signal transmitted. This signal is supplied to one input (a) of the comparator (134). To the other input (b) of the comparator, however, is supplied a signal of DC component only; thus, if the magnitude of variations of the envelope component is significantly smaller than the DC voltage level that defines the transmission power, transmission power control according to this approach works well.

However, in applications where variations of the envelope component cannot be ignored as compared to the magnitude of the DC voltage required to vary the transmission power by one step, a problem occurs such that transmission power cannot be controlled accurately. That is, because even if the result of the comparison indicates a difference between the two inputs of the comparator (134), it cannot be determined whether (i) the difference indicates that the transmission power level should be varied as the transmission power level is offset from its desired value or (ii) the transmission power level need not be varied and the aforementioned difference is caused by variations in the envelope amplitude level. Because the prior art system tries to vary the transmission power not only in case of (i) but also in case of (ii), it is feared that appropriate power control is no longer performed. Applications where accurate control of transmission power is desired include, for instance, a CDMA radio communication system. With the CDMA radio communication system, identification of one station and others is performed by use of a single code, and signals with different codes are collectively treated as noise. Regardless of the distance between a base station and a radio terminal, if the radio terminal transmits with significant transmission power, the noise level at the base station becomes very large, so that operating efficiency of the system deteriorates. Thus, with systems where a distance issue of this type is important, it is desirable that transmission power of the radio terminal be controlled as finely as possible dependent upon the distance therebetween. For example, if power is varied by +/−1 dB from a certain power level (transmission power), the resulting power variation is about +/−10 percent as converted to a voltage value. On the other hand, envelope variations for QPSK modulation or the like involve significant variations that considerably exceed +/−10 percent, because the coordinate origin is crossed during the phase shift process. Thus, for power control of +/−10 percent as described above, the envelope variation component can no longer be ignored. The present invention is intended to solve such a problem.

### BRIEF DESCRIPTION OF THE DRAWINGS

FIG. 1 shows a schematic block diagram of a prior art transmission power control circuit (100).

FIG. 2 shows a block diagram of a transmission power control circuit (200) according to a first embodiment of the present invention.

FIG. 3 shows a block diagram of a transmission power control circuit (300) according to a second embodiment of the present invention.

FIG. 4 shows a block diagram of a transmission power control circuit (400) according to a third embodiment of the present invention.

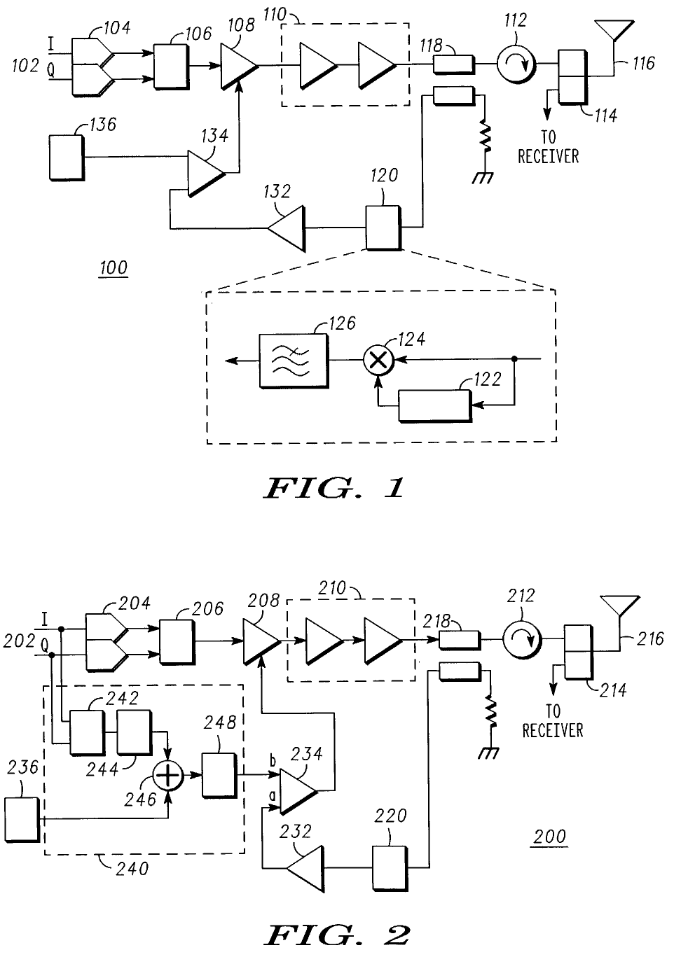

### DETAILED DESCRIPTION OF THE INVENTION

A transmission power control circuit (200, 300, 400) provided by the present invention is such that a signal to be transmitted (202, 302, 402) is amplitude-modulated to supply a transmission output signal amplified with a desired gain, and a transmission power level is determined by selecting any one of a plurality of predefined direct-current (DC) voltage levels.

The transmission power control circuit comprises: a variable-gain amplifier portion (208, 308, 408), wherein the amplitude-modulated signal is input and the amplification gain is varied according to a gain control signal; a power amplifier portion (210, 310, 410), coupled to the variable-gain amplifier portion, for supplying a transmission output signal; a branch circuit portion having a coupler (218, 318, 418) for extracting a portion of the transmission output signal and a power detector (220, 320, 420) coupled to said coupler for detecting the transmission output signal; a reference voltage generator portion (240, 340, 440) for generating a reference voltage signal, wherein said reference voltage signal is determined based on the value of the DC voltage level selected and a signal capable of extracting an envelope component of the transmission output signal; and an error detector portion (234, 334, 434) for varying the content of the gain control signal, depending on the result of comparison between the output from said branch circuit portion and said reference voltage signal.

FIG. 2 shows a block diagram of a transmission power control circuit (200) according to a first embodiment of the present invention. In the figure, similar elements in the prior art transmission power control circuit (100) are identified by like reference numerals, except they start with a “2” instead of “1”.

A new element is a reference voltage generator circuit (240) disposed between a reference voltage supply portion (236) and the other input (b) of a comparator (234) that acts as an error detector. The reference voltage generator circuit (240) includes an envelope calculator portion (242) having as its input a signal prior to being input to a modulator (206), and a delay portion (244) coupled to an output from the envelope calculator portion (242). The reference voltage generator circuit (240) further includes an adder (246) having one input thereof coupled to an output of the delay portion (244) and the other input thereof coupled to the supply portion (236), and a logarithmic amplifier (248) disposed between the output of the adder (246) and the other input (b) of the comparator (234).

The operation thereof is now described. The envelope calculator portion (242) determines a signal that represents an envelope component of the transmission output signal, based on the baseband digital orthogonal signal (202) prior to modulation. This is done by combining in-phase (I) and quadrature (Q) components and checking the amplitude and phase of the combined signal. The resulting signal that represents the envelope component is delayed at the delay portion (244). This delay adjustment is intended to adjust the phase between the path from the digital converter (204) through the coupler (218) to one input (a) of the comparator (234), and the path from the envelope calculator portion (242) through the adder (246) to the comparator (234). To the resulting phase-adjusted signal is added a signal (DC voltage) selected from the supply portion (236). Then, after scaling by the logarithmic amplifier (248), it is coupled to the other input (b) of the comparator (234). The signal supplied to the input (b) contains a DC voltage signal from the supply portion (236) and a signal representative of an envelope component from the envelope calculator portion (242). The signal supplied to one input (a) of the comparator also contains a signal representative of the envelope component (a version of A(t)·K/2 scaled by the logarithmic amplifier). Thus, because both of the inputs of the comparator (234) contain signals representative of envelope components, a situation cannot occur such that there is a difference between the two inputs of the comparator but there is no need for changing the transmission power level.

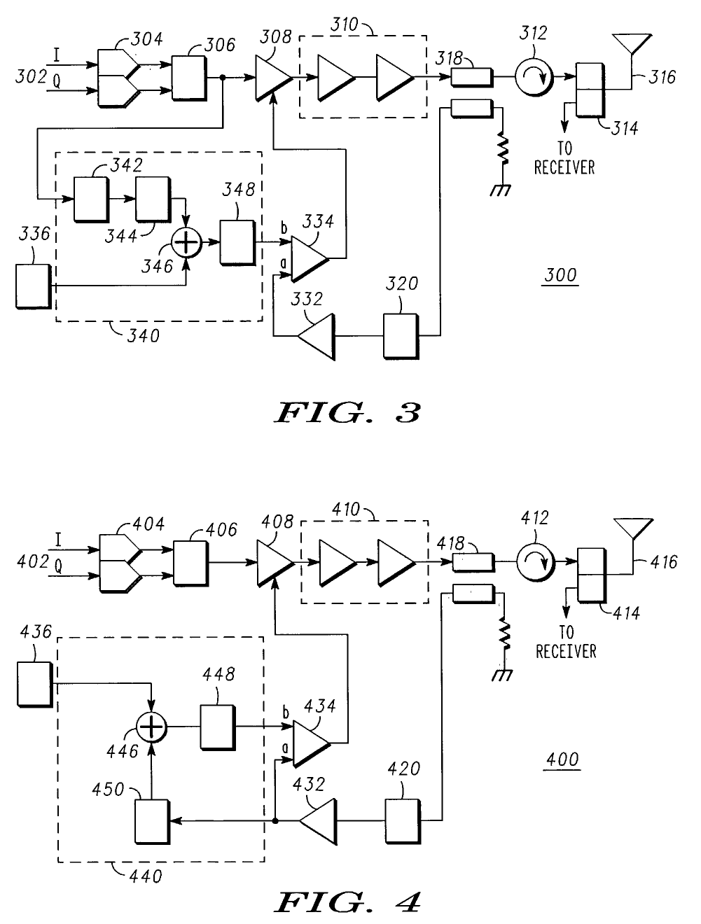

FIG. 3 shows a block diagram of a transmission power control circuit (300) according to a second embodiment of the present invention. In the figure, similar elements in the prior art transmission power control circuit (100) are identified by like reference numerals, except they start with a “3” instead of “1”.

A new element is a reference voltage generator circuit (340) disposed between a reference voltage supply portion (336) and the other input (b) of a comparator (334) that acts as an error detector. The reference voltage generator circuit (340) includes a detector (342) having as its input a signal outputted by a modulator (306), and a delay portion (344) coupled to an output from the detector (342). The reference voltage generator circuit (340) further includes an adder (346) having one input thereof coupled to the output of the delay portion (344) and the other input thereof coupled to the supply portion (336), and a logarithmic amplifier (348) disposed between the output of the adder (346) and the other input (b) of the comparator (334).

The operation thereof is now described. The detector (342) uses an IF modulation signal after modulation to determine a signal representative of an envelope component of the transmission output signal. This is done, for example, by multiplying the modulation signal and an amplitude-limited signal of that modulation signal and passing it through a low-pass filter. The resulting signal representative of an envelope component is delayed at the delay portion (344). This delay adjustment is intended to adjust the phase between the path from the output of the modulator (306) through the coupler (318) to one input (a) of the comparator (334) and the path from the detector (342) through the adder (346) to the comparator (334). A signal (DC voltage) selected from the supply portion (336) is added to the resulting phase-adjusted signal. Then, after scaling by the logarithmic amplifier (348), it is coupled to the other input (b) of the comparator (334). The signal supplied to the input (b) contains a DC voltage signal from the supply portion (336) and a signal representative of an envelope component from the detector (342). In the second embodiment, the path for phase adjustment is shorter than that required in the first embodiment. Thus, from the standpoint of facilitating phase adjustment, the second embodiment is more preferable than the first embodiment.

FIG. 4 shows a block diagram of a transmission power control circuit (400) according to a third embodiment of the present invention. In the figure, similar elements in the prior art transmission power control circuit (100) are identified by like reference numerals, except they start with a “4” instead of “1”.

A new element is a reference voltage generator circuit (440) disposed between a reference voltage supply portion (436) and the other input (b) of a comparator (434) that acts as an error detector. The reference voltage generator circuit (440) includes a direct-current (DC) breaker (450) coupled to the output of a logarithmic amplifier (432). The reference voltage generator circuit (440) further includes an adder having one input thereof coupled to the output of the DC breaker (450) and the other input thereof coupled to the supply portion (436), and a logarithmic amplifier (448) disposed between the output of the adder (446) and the other input (b) of the comparator (434).

The operation thereof is now described. The DC breaker (450) blocks the output from the logarithmic amplifier (432), that is, a DC component of the output from the power detector (420), thereby determining a signal representative of an envelope component of the transmission output signal. A signal selected from the supply portion (436) is added to the resulting signal representative of the envelope component (446). Then, after scaling by the logarithmic amplifier (448), it is coupled to the other input (b) of the comparator (434). The signal supplied to the input (b) contains a DC voltage signal from the supply portion and a signal representative of an envelope component from the detector (420). In the third embodiment, the need for phase adjustment as performed in the first and second embodiments is eliminated, so that there is an advantage in terms of simpler circuit architecture.

1. A transmission power control circuit, where a signal to be transmitted is amplitude-modulated to supply a transmission output signal amplified with a desired gain, and where a transmission power level is determined by selecting any one of a plurality of predefined direct-current (DC) voltage levels, said transmission power control circuit comprising:
a variable-gain amplifier portion, wherein the amplitude-modulated signal is input and the amplification gain is varied according to a gain control signal;
a power amplifier portion, coupled to said variable-gain amplifier portion, for supplying a transmission output signal;
a branch circuit portion having a coupler for extracting a portion of the transmission output signal and a power detector coupled to said coupler for detecting the transmission output signal;
a reference voltage generator portion for generating a reference voltage signal, wherein said reference voltage signal is determined based on the value of the DC voltage level selected and a signal capable of extracting an envelope component of the transmission output signal; and
an error detector portion for varying the content of the gain control signal, depending on the result of comparison between the output from said branch circuit portion and said reference voltage signal.

2. The transmission power control circuit according to claim 1, wherein said signal capable of extracting an envelope component of the transmission output signal is a signal prior to being input to said modulator, and wherein said reference voltage generator portion comprises:
an envelope calculator portion for creating a signal that represents an envelope component of the transmission output signal, based on said signal prior to being input to said modulator;
a delay portion for adjusting a phase of the signal that represents said envelope component; and
an adder portion for adding the DC voltage level selected to said phase-adjusted signal to generate said reference voltage signal.

3. The transmission power control circuit according to claim 1, where said signal capable of extracting an envelope component of the transmission output signal is a modulation signal output from said modulator, and wherein said reference voltage generator portion comprises:
a power detector portion for detecting said modulation signal and generating a signal that represents an envelope component of the transmission output signal;
a delay portion for adjusting a phase of the signal that represents said envelope component; and
an adder portion for adding the DC voltage level selected to said phase-adjusted signal to generate said reference voltage signal.

4. The transmission power control circuit according to claim 1, wherein said signal capable of extracting an envelope component of the transmission output signal is a signal output from said power detector, wherein a signal that represents the envelope component of the transmission output signal is generated by blocking the DC component of the signal outputted from said power detector; and
wherein the signal that represents the envelope component of the transmission output signal and the DC voltage level selected are added to create said reference voltage signal.
